(19) United States
(12) Patent Application Publication
(10) Pub. No.: US 2026/0331168 A1
(43) Pub. Date: Oct. 22, 2026

(54) SYSTEMS AND METHODS FOR MULTI-PUMPING MEMORY WITH FLIP-FLOP INTERFACE

(71) Applicant: Taiwan Semiconductor Manufacturing Company, Ltd., Hsinchu (TW)

(72) Inventors: YOSHISATO YOKOYAMA, Hsinchu City (TW); MASARU HARAGUCHI, Hsinchu City (TW); YORINOBU FUJINO, Hsinchu City (TW); TAKUMI HARA, Hsinchu City (TW)

(73) Assignee: Taiwan Semiconductor Manufacturing Company, Ltd., Hsinchu (TW)

(21) Appl. No.: 19/721,707

(22) Filed: Jun. 26, 2026

Related U.S. Application Data
(63) Continuation of application No. 18/894,494, filed on Sep. 24, 2024.

(51) Int. Cl. G11C 11/419; G11C 7/22; G11C 11/412; G11C 11/418; H03K 3/037

(52) U.S. Cl. CPC G11C 11/419; G11C 7/222; G11C 11/412; G11C 11/418; H03K 3/037

(57) ABSTRACT

A memory circuit includes a memory array comprising a plurality of memory cells. The memory circuit includes a low-through latch (LL) coupled to a pin and a control line, wherein the control line carries a clock signal. The memory circuit includes a high-through latch (HL) coupled to the LL, the control line, and the memory array. The HL is configured to propagate signals when the clock signal is high and stop propagation of the signals when the clock signal is low. The LL is configured to propagate signals when the clock signal is low and stop propagation of the signals when the clock signal is high.

### CROSS-REFERENCE TO RELATED APPLICATION

This application is a continuation of U.S. patent application Ser. No. 18/894,494, filed Sep. 24, 2024, which is incorporated herein by reference in its entirety.

### BACKGROUND

Developments in electronic devices, such as computers, portable devices, smart phones, internet of thing (IoT) devices, etc., have prompted increased demands for memory devices. In general, memory devices may be volatile memory devices or non-volatile memory devices. Volatile memory devices can store data while power is provided but may lose the stored data once the power is shut off. Unlike volatile memory devices, non-volatile memory devices may retain data even after the power is shut off but may be slower than the volatile memory devices.

### BRIEF DESCRIPTION OF THE DRAWINGS

Aspects of the present disclosure should be understood from the following detailed description with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic block diagram of an example memory device, in accordance with some embodiments.

FIG. 2 illustrates a schematic diagram of an example static random access memory (SRAM) cell in the memory device of FIG. 1, in accordance with various embodiments.

FIG. 3 illustrates a schematic diagram of flip-flop interfaces used for the memory device of FIG. 1, in accordance with various embodiments.

FIG. 4 illustrates schematic diagrams of the flip-flop interfaces of FIG. 3, in accordance with various embodiments.

FIG. 5 illustrates an example timing diagram for the operation of the memory device using the flip-flop interfaces of FIG. 3, in accordance with various embodiments.

FIG. 6 illustrates a schematic diagram of scan flip-flop interfaces used for the memory device of FIG. 1, in accordance with various embodiments.

FIG. 7 illustrates a schematic diagram of separating read signals and write signals from a common pin for the memory device using the scan flip-flop interfaces of FIG. 6, in accordance with various embodiments.

FIG. 8 illustrates an example timing diagram for the operation of the memory device using the scan flip-flop interfaces of FIG. 6 with the separated read and write signals of FIG. 7, in accordance with various embodiments.

FIG. 9 illustrates a schematic diagram of the memory device using the flip-flop interfaces of FIG. 3 and including multiplexers for selecting an operation mode, in accordance with various embodiments.

FIG. 10 illustrates a flow of an example method for forming the memory device of at least one of FIGS. 1-9, in accordance with some embodiments.

FIG. 11 illustrates a flow of an example method for operating the memory device of at least one of FIGS. 1-9, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Memory circuits or devices can include various components for accessing memory cells within a memory array. These components may include, for example, at least one of address decoders, row and column selectors, sense amplifiers, write drivers, or control logic. The address decoder can interpret memory addresses to select specific rows or columns within the memory array. The row and column selectors can facilitate in addressing of memory cells by directing the selected row and column signals to the desired memory locations, e.g., for reading from or writing to the located memory cells. The sense amplifier can amplify the signals retrieved during read operations to facilitate reading data from the memory cells. The write driver can deliver the data to be stored into the selected memory cells. The control logic can manage the timing and sequencing of memory operations, ensuring accurate data retrieval and storage. Other components can be included as part of the memory device, configured to operate collectively to provide the features or functionalities of the memory device for accessing the memory cells.

In various cases, the integrated circuits may include static random access memory (SRAM) circuits to provide on-chip data storage. An SRAM circuit can be configured to meet specific design requirements associated with the surrounding circuitry attached to the SRAM circuit. One type of SRAM circuit may be configured to provide one port for either read or write access to data stored within the SRAM circuit. The address inputs to such a circuit are typically shared for both read and write access. Another common type of SRAM circuit, referred to as a two-port SRAM circuit, may include a pseudo-two-port (P2P) SRAM configured to provide two ports for accessing data stored within the SRAM circuit. Two-port SRAM circuits may include a first port for read accesses (e.g., read port) and a second port for write accesses (e.g., write port). The read and write operations of the two-port SRAM circuits can be performed within individual clock cycles, such as a read access and a write access operation within one clock cycle. Each port of the two-port SRAM circuit is typically capable of asynchronous, independent access to data stored within the SRAM circuit, allowing the two-port SRAM circuit to be incorporated into a range of different applications with different usage models. The one or more ports of the circuit can be referred to as pins. Other types of SRAM circuits can be discussed herein, not limited to the two-port SRAM circuit (e.g., P2P SRAM), such as pseudo-three-port (P3P), pseudo-four-port (P4P), pseudo-dual-port (PDP) SRAM, etc.

In certain systems, one or more pins (or ports) for read and write operations can be coupled to a respective latch configured to control the propagation and storage of signals or data based on the state of the clock. This latch may be a low-through latch (LL) configured to propagate signals during a low state of the clock (e.g., logic low) and maintain stored data (e.g., one bit of data) or signals during a high state of the clock (e.g., logic high). For instance, the clock signal or enable signal input to the latch can control whether to store the input data or maintain the current data or value. During the low state, the LL can be transparent, allowing the propagation of the input signal to the output. By allowing the propagation of the input signal to the output, the LL may change the stored data to the input data corresponding to the input signal (e.g., storing the input data). During the high state, the LL can maintain the current data (or value) stored prior to switching from the logic low to the logic high of the clock cycle, for example.

The LL may be used in relation to the read and write operations performed within one clock cycle of a multi-pumping memory, for instance, to prevent changes in the data during each read or write operation. For purposes of providing examples, the usage of the latch may be described in relation to the write operation. For example, responsive to triggering a clock signal (e.g., logic high), a read clock can be generated or set to a high state followed by a write clock. Before the read operation (e.g., before the read clock is in a high state), the LL can be in a low state to allow propagation or changes to the stored data. During the read and write operations (e.g., when the read and/or write clocks are in the high state), the LL can be set to a high state to maintain the currently stored value or propagated data during the read and/or write operations.

In further examples, to ensure proper execution of the write operation and signal stability, hold racing can be configured for a predefined duration after the falling clock edge of the write clock (in a read-to-write sequence). The hold racing can refer to a predefined hold time for at least one clock signal to prevent premature data transition or change after the write clock edge, for example. In this case, the hold racing may be applied to the latch clock, such that the LL is maintained in the high state for the predefined duration after the falling clock edge of the write clock, e.g., when the write clock transitions from the high state to the low state. Applying the hold racing for the LL can ensure the current (write) data is maintained during the write operation, for example. However, implementing the hold racing may impact the cycle time because of the delay applied to the latch clock. Further, because input pins consume power from respective pins to a meeting point with a clock element, such as at least one of the latch, a word line (WL) decoder, read circuit, write circuit, etc., having one latch to control the propagation of the input signals may consume excessive power from connection with various components of the device or circuit.

The systems and methods of the technical solution can provide various embodiments or configurations of a memory device for multi-pumping memory with flip-flop interface. In some configurations, the systems and methods can provide a plurality of flip-flops coupled to respective input pins. Each flip-flop can include two latches, e.g., a first latch and a second latch. The first latch can correspond to a low-through latch (LL) and the second latch can correspond to a high-through latch (HL). The latches can operate according to a latch clock or a control signal comprising a first (low) state and a second (high) state. In the low state, the LL can allow signal propagation and storage of the input signal, and the HL can stop signal propagation and maintain the current data. In the high state, the LL can stop signal propagation and maintain the current data, and the HL can allow signal propagation and storage of the input signal.

The systems and methods can maintain data for an upcoming or next access clock cycle using the HL, e.g., the write clock cycle. For example, before generating a high read clock signal, the latch clock corresponding to the read clock can be in the low state, thereby allowing (data or signal) propagation through the LL and stopping the propagation at the HL. The LL can store the value of the input signal from the respective input pin. When the read clock is generated, the latch clock can be set to the high state. In the latch clock high state, the LL can stop propagation and the HL can allow propagation. The value (or state) stored in the LL can be the input data to the HL, where the HL can store the input data for the next (or upcoming) write operation (e.g., when the write clock is set to the high state).

In further examples, the write clock can be generated to initiate a write operation to the memory array after a predefined timeframe from generating the read clock. During the write operation, the value stored in the HL can be provided as input into the memory array. Storing the input data in the HL can be a part of a setup for the write operation. For instance, the predefined time duration from around a rising edge of the latch clock to a rising edge of the write clock can be referred to as setup racing, e.g., for setting up the write data for the write operation. With the flip-flop implementation, the latch clock can be set to a low state according to the state of the read clock because the HL can maintain the current data for the write operation, while the LL can store its input data for subsequent access operation. Therefore, hold racing (e.g., the delay after the falling edge of the write clock) can be removed and replaced with the setup racing, thereby reducing the cycle time to perform the read and write operations. Further, the implementation of the flip-flop can minimize power consumption because the power consumption can be reduced to, for instance, between the one or more input pins and one of the respective LL or HL, corresponding to the meeting point with the clock signal, e.g., instead of the between the input pins and the various other components downstream from the input pins of the memory device. For purposes of providing examples, the example usage of the flip-flop interface for the multi-pumping memory may be described in relation to the write operation, although it should be noted that the flip-flop can be implemented for other access operations, such as for the read operation.

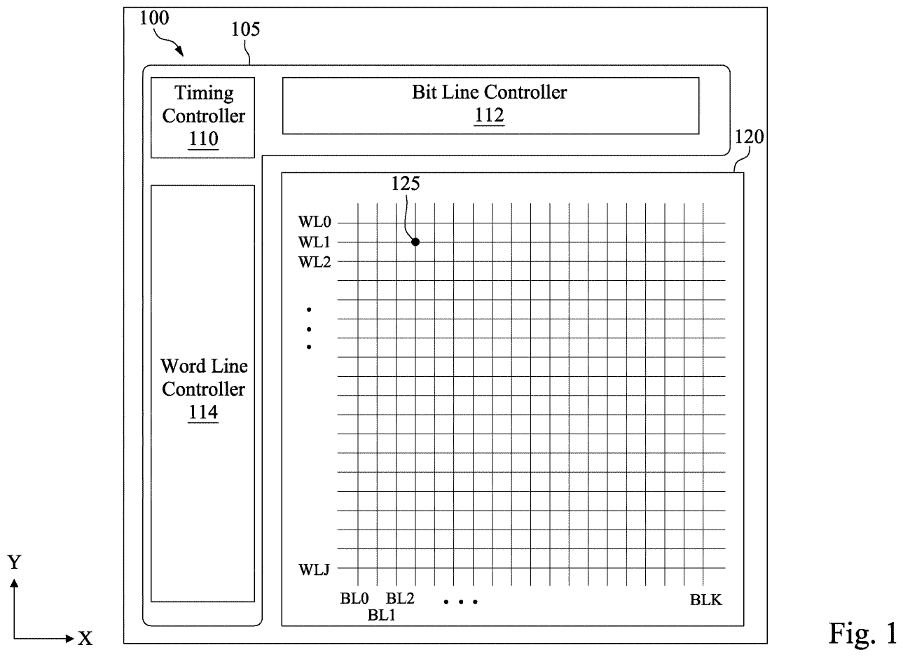

FIG. 1 is a diagram of a memory device 100, in accordance with one embodiment. In some embodiments, the memory device 100 includes a memory controller 105 and a memory array 120. The memory array 120 may include a plurality of storage circuits or memory cells 125 arranged in two-or three-dimensional arrays. Each memory cell 125 may be coupled to a corresponding word line WL and a corresponding bit line BL. The memory controller 105 may write data to or read data from the memory array 120 according to electrical signals through word lines WL and bit lines BL. In other embodiments, the memory device 100 includes more, fewer, or different components than shown in FIG. 1.

The memory array 120 is a hardware component that stores data. In one aspect, the memory array 120 is embodied as a semiconductor memory device. The memory array 120 includes a plurality of storage circuits or memory cells 125. The memory array 120 includes word lines WL0, WL1 . . . WLJ, each extending in a first direction (e.g., X-direction) and bit lines BL0, BL1 . . . BLK, each extending in a second direction (e.g., Y-direction). The word lines WL and the bit lines BL may be conductive metals or conductive rails. In one configuration, each memory cell 125 is coupled to a corresponding word line WL and a corresponding bit line BL, and can be operated according to voltages or currents through the corresponding word line WL and the corresponding bit line BL. In some embodiments, each bit line includes bit lines BL, BLB coupled to one or more memory cells 125 of a group of memory cells 125 disposed along the second direction (e.g., Y-direction). The bit lines BL, BLB may receive and/or provide differential signals. Each memory cell 125 may include a volatile memory, a non-volatile memory, or a combination of them. In some embodiments, each memory cell 125 is embodied as a static random access memory (SRAM) cell or other type of memory cell. In some embodiments, the memory array 120 includes additional lines (e.g., select lines, reference lines, reference control lines, power rails, etc.).

The memory controller 105 is a hardware component that controls operations of the memory array 120. In some embodiments, the memory controller 105 includes a bit line controller 112, a word line controller 114, and a timing controller 110. The bit line controller 112, the word line controller 114, and the timing controller 110 may be embodied as logic circuits, analog circuits, or a combination of them. In one configuration, the word line controller 114 is a circuit that provides a voltage or current through one or more word lines WL of the memory array 120, and the bit line controller 112 is a circuit that provides or senses a voltage or current through one or more bit lines BL of the memory array 120. In one configuration, the timing controller 110 is a circuit that provides control signals or clock signals to synchronize operations of the bit line controller 112 and the word line controller 114. In some embodiments, the timing controller 110 is embodied as or includes a processor and a non-transitory computer readable medium storing instructions when executed by the processor cause the processor to execute one or more functions of the timing controller 110 or the memory controller 105 described herein. The bit line controller 112 may be coupled to bit lines BL of the memory array 120, and the word line controller 114 may be coupled to word lines WL of the memory array 120. In some embodiments, the memory controller 105 includes more, fewer, or different components than shown in FIG. 1.

In one example, the timing controller 110 may generate control signals to coordinate operations of the bit line controller 112 and the word line controller 114. In one approach, to write data at a memory cell 125, the timing controller 110 may cause the word line controller 114 to apply a voltage or current to the memory cell 125 through a word line WL coupled to the memory cell 125 and cause the bit line controller 112 to apply a voltage or current corresponding to data to be stored to the memory cell 125 through a bit line BL coupled to the memory cell 125. In one approach, to read data from a memory cell 125, the timing controller 110 may cause the word line controller 114 to apply a voltage or current to the memory cell 125 through a word line WL coupled to the memory cell 125 and cause the bit line controller 112 to sense a voltage or current corresponding to data stored by the memory cell 125 through a bit line BL coupled to the memory cell 125.

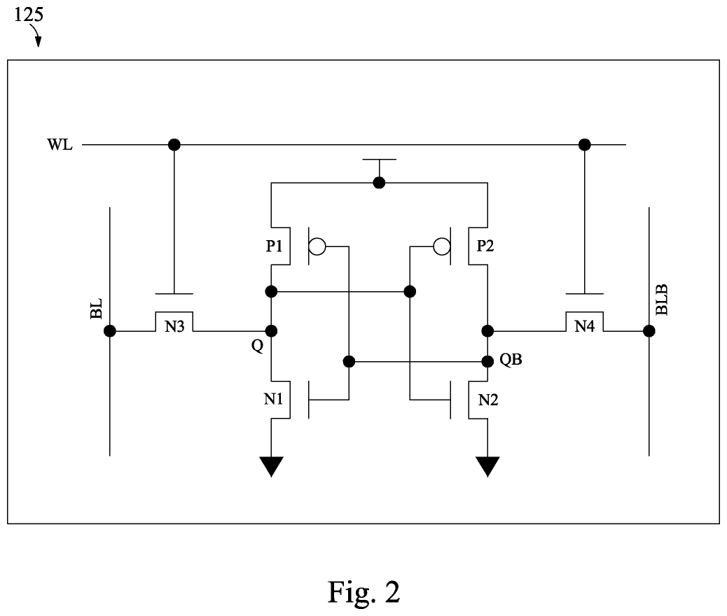

FIG. 2 is a schematic diagram of an example SRAM cell 125, in accordance with one embodiment. The SRAM cell 125 can be a P2P six-transistor (6T) SRAM, configured to read and write in individual cycles. Although a P2P 6T SRAM is used as an example, other types of SRAM cells may be provided or utilized to perform the features, functionalities, or operations discussed herein. In some embodiments, the SRAM cell 125 includes N-type transistors N1, N2, N3, N4 and P-type transistors P1, P2. The N-type transistors N1, N2, N3, N4 may be N-type metal-oxide-semiconductor field-effect transistors (MOSFET) or N-type fin field-effect transistors (FinFET). The P-type transistors P1, P2 may be P-type MOSFET or P-type FinFET. These components may operate together to store a bit. In other embodiments, the SRAM cell 125 includes more, fewer, or different components than shown in FIG. 2.

In some configurations, the N-type transistors N3, N4 include gate electrodes coupled to a word line WL. In some configurations, a drain electrode of the N-type transistor N3 is coupled to a bit line BL, and a source electrode of the N-type transistor N3 is coupled to a port Q. In some configurations, a drain electrode of the N-type transistor N4 is coupled to a bit line BLB, and a source electrode of the N-type transistor N4 is coupled to a port QB. In certain aspects, the N-type transistors N3, N4 operate as electrical switches. The N-type transistors N3, N4 may allow the bit line BL to electrically couple to or decouple from the port Q and allow the bit line BLB to electrically couple to or decouple from the port QB, according to a voltage applied to the word line WL. For example, according to a supply voltage VDD (or 1V) corresponding to a high state (or logic value ‘1’) applied to the word line WL, the N-type transistor N3 is enabled to electrically couple the bit line BL to the port Q and the N-type transistor N4 is enabled to electrically couple the bit line BLB to the port QB. For another example, according to a ground voltage VSS (or 0V) corresponding to a low state (or logic value ‘0’) applied to the word line WL, the N-type transistor N3 is disabled to electrically decouple the bit line BL from the port Q and the N-type transistor N4 is disabled to electrically decouple the bit line BLB from the port QB.

In some configurations, the N-type transistor N1 includes a source electrode coupled to a first supply voltage rail supplying the ground voltage VSS or 0V, a gate electrode coupled to the gate electrode of the P-type transistor P1, and a drain electrode coupled to the port Q. In some configurations, the P-type transistor P1 includes a source electrode coupled to a second supply voltage rail supplying the supply voltage VDD, a gate electrode coupled to the gate electrode of N-type transistor N1, and a drain electrode coupled to the port Q. In some configurations, the N-type transistor N2 includes a source electrode coupled to the first supply voltage rail supplying the ground voltage VSS or 0V, a gate electrode coupled to the port Q, and a drain electrode coupled to the port QB. In some configurations, the P-type transistor P2 includes a source electrode coupled to the second supply voltage rail supplying the supply voltage VDD, a gate electrode coupled to the port Q, and a drain electrode coupled to the port QB. In such configurations, the N-type transistor N1 and the P-type transistor P1 operate as an inverter, and the N-type transistor N2 and the P-type transistor P2 operate as an inverter, such that two inverters form cross-coupled inverters. In one aspect, the cross-coupled inverters may sense and amplify a difference in voltages at the ports Q, QB. When writing data, the cross-coupled inverters may sense voltages at the ports Q, QB provided through the N-type transistors N3, N4 and amplify a difference in voltages at the bit lines BL, BLB. For example, the cross-coupled inverters sense a voltage 0.5 V at the port Q and a voltage 0.4V at the port QB, and amplify a difference in the voltages at the ports Q, QB through a positive feedback (or a regenerative feedback) such that the voltage at the port Q becomes the supply voltage VDD (e.g., 1V) and the voltage at the port QB becomes the ground voltage VSS (e.g. 0V). The amplified voltages at the ports Q, QB may be provided to the bit lines BL, BLB through the N-type transistors N3, N4, respectively for reading.

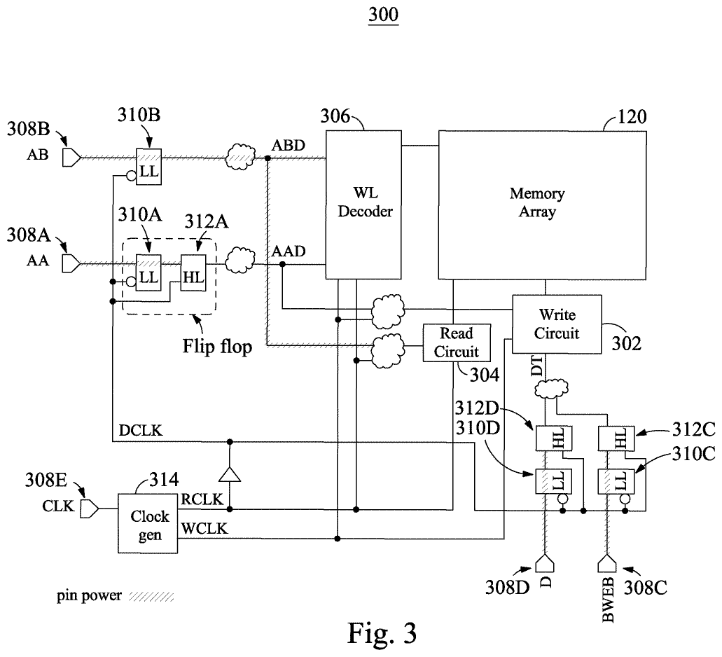

FIG. 3 illustrates a schematic diagram 300 of flip-flop interfaces used for the memory device 100 of FIG. 1, in accordance with various embodiments. The schematic diagram 300 of FIG. 3 shows an example of using flip-flop interfaces for access operations (e.g., read and/or write operations) for multi-pumping memory (e.g., SRAM). The components or circuits of the schematic diagram 300 can be a part of the memory device 100. As shown, the schematic diagram 300 includes at least the memory array 120 comprising a plurality of memory cells 125, a write circuit 302, a read circuit 304, a word line (WL) decoder 306, a plurality of input pins 308A-E, a plurality of low-through latches (LLs) 310A-D, a plurality of high-through latches (HLs) 312A, 312C, 312D, and a clock generator 314. In some cases, the one or more components of the schematic diagram 300 can be coupled to one of the memory cells 125 within the memory array 120. The various components of the memory device 100 can operate to perform read and write operations within one clock cycle.

The input pins 308A-E may sometimes be referred to as input ports, input terminals, input lines, or input points. The input pins 308A-E may sometimes be referred to as input pin(s) 308. For instance, references to the input pins 308A-E discussed herein may be referred to as input ports, among others. The input pins 308A-E can include at least one of but not limited to address pins 308A-B, a bit write enable bit (BWEB) pin 308C, data pin 308D, and clock pin 308E. Each of the input pins 308A-E may sometimes be referred to generally as pins 308A-E, respectively.

The address pin 308A can be referred to as address pin AA. The address pin 308B can be referred to as address pin AB. The address pin 308A can be used for addressing the memory array 120 for the write operation, e.g., accessing at least one memory cell 125 to write or store data. The address pin 308B can be used for the read operation, e.g., accessing at least one memory cell 125 to read the corresponding stored data. Each of the address pins 308A-B can carry respective signals including address data or values. For example, as shown in the schematic diagram 300, the address data from the address pin 308A can be labeled as “AAD”, e.g., address pin AA data. In another example, the address data from the address pin 308B can be labeled as “ABD”, e.g., address pin AB data. The address data from at least one of the address pins 308A-B can be provided as input to at least one of the write circuit 302, the read circuit 304, or the WL decoder 306, among others.

The BWEB pin 308C can provide a control signal used in the memory device 100 to allow/enable selective writing of individual bits within a data word. The BWEB pin 308C may provide a signal indicative of which one or more bits in the memory array 120 are to be written with the provided data (e.g., from the data pin 308D). For example, when the BWEB signal (e.g., data or value) from the BWEB pin 308C is asserted for one or more bits, the one or more bits can be written to, while the remaining bits in the data word can be maintained or remain unchanged. The BWEB data can be a part of the write data or data for the write operation.

The data pin 308D can carry or provide a data signal including the data or value to be written in at least one memory cell 125 of the memory array 120. The data from the data pin 308D can be a part of the write data for the write operation. For example, signals from the BWEB pin 308C and the data pin 308D can form the write data (e.g., value or data for the write operation), labeled as “DT” in the schematic diagram 300. The data from the data pin 308D can be used concurrently with the corresponding address value from the address pin 308A, for instance, to write to or store the write data in the desired memory cell(s) 125.

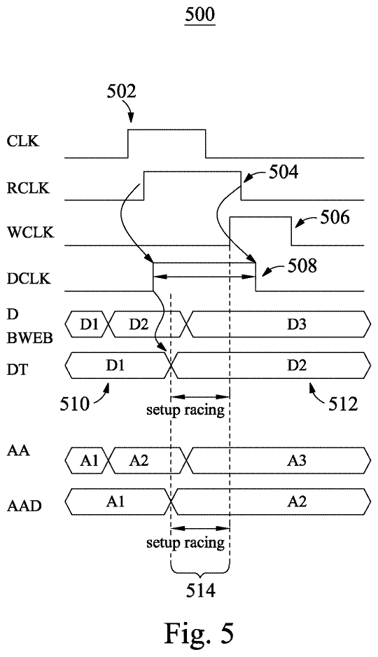

The clock pin 308E can sometimes be referred to as a clock input or a clock signal pin. The clock pin 308E can provide a (clock) signal for starting a clock cycle. Each clock cycle can have a predefined cycle time. The clock signal can include a periodic waveform that oscillates between a high state or signal (e.g., ‘1’) and a low state or signal (e.g., ‘0’). The timing of the clock cycle can be based on a predefined clock frequency based on the specification or configuration of the memory device 100, for example. In various implementations, a high signal carried by the clock pin 308E can trigger the start of the read and write operations of the memory device 100. The clock signal from the clock pin 308E can be input to the clock generator 314. As shown in the schematic diagram 300, the clock signal can be labeled as “CLK”. The timing of the various clocks can be described in conjunction with at least FIG. 5.

The clock generator 314 can receive the clock signal via the clock pin 308E. The clock generator 314 can generate and output a plurality of access clock signals according to the input clock signal. In some implementations, generating an access clock signal can involve setting the access clock signal to a high state or value (e.g., ‘1’) to trigger the corresponding access operation. For instance, the plurality of access clock signals can include a first (access) clock signal and a second (access) clock signal. The clock generator 314 can generate the first clock signal (e.g., setting the first clock to a high state) in response to receiving the high CLK (e.g., a high state of the CLK). The clock generator 314 can generate the second clock signal (e.g., setting the second clock to a high state) after a predefined time period from generating the first clock signal. The duration of setting each of the first (access) clock and the second (access) clock to the high state can be predefined.

As shown in the schematic diagram 300, for example, the first clock can correspond to a read clock (e.g., labeled as “RCLK”) and the second clock can correspond to a write clock (e.g., labeled as “WCLK”). For purposes of providing examples herein, each clock cycle can start a read-then-write operation. In such cases, the clock generator 314 can generate a read clock signal (e.g., the read clock set to ‘1’) for a predefined duration for the one or more components of the memory device 100 to perform the read operation. After a predefined duration from generating the read clock signal, the clock generator 314 can generate a write clock signal (e.g., the write clock set to ‘1’) for a predefined duration for the one or more components of the memory device 100 to perform the write operation. In various implementations, the clock generator 314 can generate the desired clock signals for synchronizing the operation of the one or more components discussed herein, for instance, to ensure the data is latched, read, or written in sync with the overall system timing. The write clock signal can be input to the write circuit 302 to perform the write operation. The read clock signal can be input to the read circuit 304 to perform the read operation. The example timing of the read and write clocks can be described in conjunction with at least FIG. 5.

The signals from the input pins 308A-E discussed herein may be generated by other components or circuits of the memory device 100 and transmitted or propagated via the respective input pins 308A-E. It should be noted that additional input pins may be included for accessing the memory array 120 or other memory cells 125 within the memory array 120, not limited to the input pins described in FIG. 3, for example.

The write circuit 302 can perform the write operation for the memory device 100. The write circuit 302 can receive write data DT from the BWEB pin 308C and the data pin 308D. The write data DT can include data or value from the BWEB pin 308C and the data pin 308D. For example, the write circuit 302 can use the BWEB data to determine which bits of at least one memory cell 125 in the memory array 120 are written using the data from the data pin 308D. The write circuit 302 can receive the address data AAD from the address pin 308A. The write circuit 302 can use the address data AAD to determine or select the at least one memory cell 125 within the memory array 120 to perform the write operation using the write data DT (or store the write data DT). The write circuit 302 can receive the WCLK (e.g., write clock) signals from the clock generator 314. The write circuit 302 can perform the write operation during the high state of the WCLK. The write circuit 302 can suspend or stop the write operation during the low state of the WCLK.

The read circuit 304 can perform the write operation for the memory device 100. The read circuit 304 can receive the address data ABD from the address pin 308B. The write circuit 302 can use the address data ABD to determine or select the at least one memory cell 125 within the memory array 120 to perform the read operation, e.g., to read from the at least one memory cell 125. The read circuit 304 can receive the RCLK (e.g., read clock) signals from the clock generator 314. The read circuit 304 can perform the read operation during the high state of the RCLK. Performing the read operation can involve reading or retrieving data from the at least one memory cell 125 according to the address data ABD. The read circuit 304 can suspend or stop the read operation during the low state of the RCLK. For the read-then-write operation, the read circuit 304 can perform the read operation before the write operation, e.g., controlled according to the RCLK and WCLK signals. For the write-then-read operation, the read circuit 304 can perform the read operation after the write operation. In some implementations, the read circuit 304 can output the read data to one or other components or circuits of the memory device 100 or one or more external devices (not shown) coupled to the memory device 100.

The WL decoder 306 can operate to decode the address signals from the address pins 308A-B, e.g., the latched address signals from one of the LL 310A-B or the HL 312A. For example, the WL decoder 306 can receive at least one of the address data AAD or the address data ABD. The WL decoder 306 can decode at least one of the address data AAD or the address data ABD to determine the WL of the memory array 120 to access, such as for the write circuit 302 to perform the write operation or the read circuit 304 to perform the read operation. The timing of the WL decoder 306 can be controlled according to the RCLK signal or the WCLK signal. In some cases, the WL decoder 306 can use the address data ABD during the high state of the RCLK signal to perform the read operation. In some other cases, the WL decoder 306 can use the address data AAD during the high state of the WCLK signal to perform the write operation. In various configurations, the clock generator 314 can send the RCLK and/or WCLK signals to the one or more components of the memory device 100 to synchronize or control the operation time of each component to perform the read and write operations.

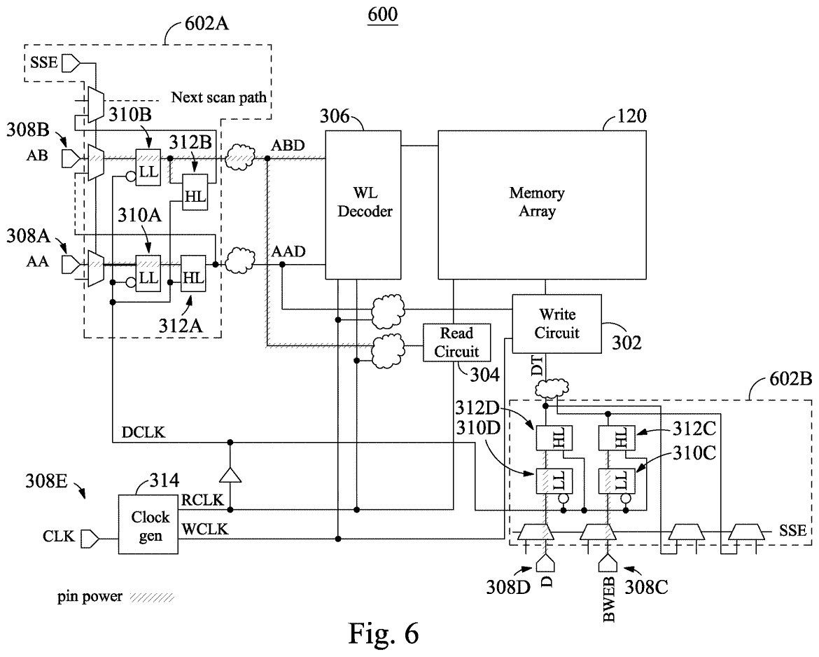

The memory device 100 can include the LLs 310A-D and the HLs 312A-D (e.g., HL 312B described in conjunction with at least FIG. 6) configured to store or latch value or data from the input signals via the respective input pins 308A-D. The LLs 310A-D can sometimes be referred to as LL(s) 310. The HLs 312A-D can sometimes be referred to as HL(s) 312. As shown in the schematic diagram 300, the LLs 310A-D can be coupled to the input pins 308A-D, respectively. The HLs 312A, 312C, 312D can be coupled to the LLs 310A, 310C, 310D, respectively. For example, the outputs from the LLs 310A, 310C, 310D can be inputs to the HL 312A, 312C, 312D. In various arrangements, the signals or data from the one or more input pins 308A-D can be stored by or propagated via one or more LLs 310 and/or HLs 312 to perform at least one of the read operation and/or the write operation.

Coupling the HL 312 to the respective LL 310 can form a flip-flop (e.g., sometimes referred to as a flip-flop interface). For example, the schematic diagram 300 shows a plurality of flip-flops, including at least a first flip-flop, a second flip-flop, and a third flip-flop. The first flip-flop can include the LL 310A coupled to the HL 312A. The second flip-flop can include the LL 310D coupled to the HL 312D. The third flip-flop can include the LL 310C coupled to the HL 312C. The memory device 100 can include more or less flip-flops, not limited to the three flip-flops shown in conjunction with at least FIG. 3.

In some implementations, an output from the HL 312 can be referred to as an output from a flip-flop. For example, the output from the HL 312A can be referred to as the output from the first flip-flop, the output from the HL 312D can be referred to as the output from the second flip-flop, the output from the HL 312C can be referred to as the output from the third flip-flop, etc.

The one or more LLs 310 and/or HLs 312 can interpose between the respective input pins 308A-D and at least one of the write circuit 302, read circuit 304, WL decoder 306, or the memory array 120 to allow or stop signal propagation from the input pins 308A-D. The LLs 310 and/or HLs 312 can allow or stop the signal propagation according to a latch clock signal (e.g., sometimes referred to as a latch control signal) from the clock generator 314. The latch clock signal can be labeled as “DCLK”, where the DCLK signal can be carried via a DCLK line (e.g., sometimes referred to as a control line to control the LLs 310 and the HLs 312). The DCLK signal can correspond to the RCLK signal, such that generating a high RCLK signal (e.g., setting the RCLK signal to the high state or ‘1’) leads to a high DCLK signal (e.g., setting the DCLK signal to the high state). Conversely, for example, setting a low RCLK signal (e.g., setting the RCLK signal to the low state or ‘0’) can result in a low DCLK signal (e.g., setting the DCLK signal to the low state).

Allowing signal propagation via at least one of the latches (e.g., at least one of the LLs 310 or HLs 312) can refer to or involve enabling the latch to pass the input signal to the output. The latch can be transparent to allow the signal propagation. By allowing the propagation of the input signal through the latch, the latch can store the data (or value) of the input signal (e.g., store the bit value). Storing the data of the input signal may involve changing or replacing a current stored data with the input data. The LLs 310 or HLs 312 stopping signal propagation can refer to or involve preventing the latch from passing changes in the input signal to the output, e.g., blocking the input signal from passing the latch. By stopping the propagation, the latch can hold or maintain the current data or value. The data or value stored in the latch can be referred to as a latch state.

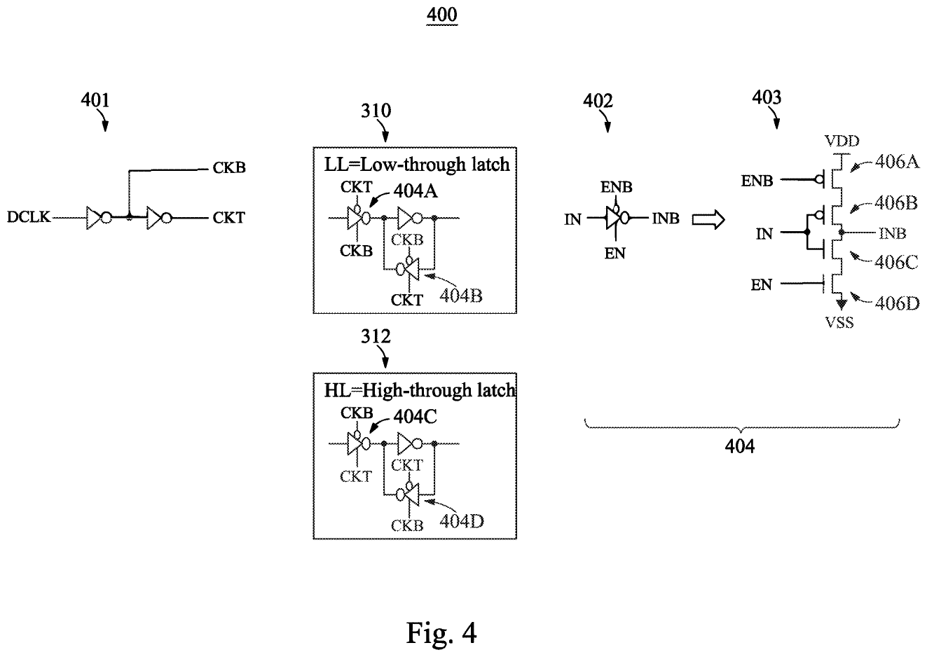

In some implementations, the latched value (e.g., the value stored in the latch) can be used by at least one component of the memory device 100 coupled to the respective latch, for instance, to access the desired memory cell 125 or perform an access operation including read or write operation. Components of the LL 310 and the HL 312 can be described in conjunction with at least FIG. 4. The timing of the latch clock for enabling or disabling the LLs 310 or the HLs 312 and the changes to the write data DT and/or the address AAD according to the state of the latches can be described in conjunction with at least FIG. 5. It should be noted that one or more intermediary components or circuits can be formed, implemented, or coupled between the one or more input pins 308A-B and the memory array 120, not limited to the LLs 310 and/or the HLs 312.

For purposes of providing examples, the latches (e.g., at least one of LLs 310 or HLs 312) can be operated to control the timing of the respective data to provide input to the one or more components. For example, the memory device 100 can operate at least one of the LL 310B to regulate (or control) the timing of address ABD transitions (e.g., changes to the address ABD), the LL 310A and HL 312A to regulate the timing of AAD transitions, and the LLs 310C-D and HLs 312C-D to regulate the timing of write data DT transitions according to the DCLK signal.

FIG. 4 illustrates schematic diagrams 400 of the flip-flop interfaces of FIG. 3, in accordance with various embodiments. The schematic diagrams 400 show the internal components of the LLs 310 and the HLs 312 corresponding to the flip-flop interface used in the memory device 100 as described in at least FIG. 3. As shown in schematic diagram 401, a portion of a latch (e.g., LL 310 or HL 312) can include a clock true (CKT) line and a clock bar (CKB) line coupled to the DCLK line (e.g., the line carrying the DCLK signal or the latch clock signal). In this case, the CKB line can carry the inverse of the DCLK signal (e.g., the signal from the CKB line is opposite from the DCLK signal) and the CKT line can carry the DCLK signal (e.g., the signal from the CKT line corresponds to the DCLK signal) to a plurality of tri-state buffers 404A-D of the latch. The tri-statue buffers 404A-D can sometimes be referred to as buffer(s) 404 configured to receive an input signal and two enable signals.

For example, if the DCLK signal is ‘1’ (e.g., in the high state), the CKT signal of the CKT line can be ‘0’ (e.g., in the low state) and the CKB signal of the CKB line can be ‘1’. If the DCLK signal is ‘0’, the CKT signal can be ‘1’ and the CKB signal can be ‘0’. The CKT and CKB signals can be fed as inputs to the enable ports of the buffers 404. For example, schematic diagram 402 shows a representation or symbol of a buffer 404 (e.g., tri-state buffer). As shown in the schematic diagram 402, the buffer 404 can include an input port (e.g., labeled as “IN”) configured to receive an input signal, two enable ports including a first enable port and a second enable port (e.g., labeled as “EN” and “ENB”) configured to receive enable signals, and an output port (e.g., labeled as “INB”).

In various implementations, the enable ports of the buffer 404 can receive the CKT signal and the CKB signal. For example, the ENB and EN ports of the buffers 404A and 404D can receive the CKT and CKB signals, respectively. Hence, signals to the ENB and EN ports can be the inverse of each other. In another example, the ENB and EN ports of the buffers 404B and 404C can receive the CKB and CKT signals, respectively. Each latch can include two buffers, e.g., the LL 310 can include the buffers 404A-B and the HL 312 can include the buffers 404 C-D.

In further examples, schematic diagram 403 shows the internal components of the buffer 404, including a plurality of n-channel metal-oxide semiconductors (NMOS) (e.g., 406C-D) and p-channel metal-oxide semiconductors (PMOS) (e.g., 406A-B). According to the signals (e.g., clock signals), the buffer 404 may either allow the transmission of the input signals (e.g., received via the input port IN) to the output or disconnect the input port from the output, thereby stopping signal transmission. For example, the gate of the PMOS 406A can correspond to the ENB port and the gate of the NMOS 406D can correspond to the EN port. The gates of the PMOS 406B and the NMOS 406C can correspond to the input port IN. When the EN port is high (e.g., ‘1’) and the ENB port is low (e.g., ‘0’), the input signal from the input port IN can be passed to the output port INB. The buffer 404 can be considered as activated or “ON” when the input signal is allowed to pass to the output. Otherwise, when the EN port is low and the ENB port is high, the output port INB can be in a high-impedance state, thereby effectively disconnected from the input port IN (or disconnected from the circuit). The buffer 404 can be considered as deactivated, “OFF”, or disconnected when the input signal is blocked or prevented from being passed or propagated to the output. It should be noted that, although the input signal passed to the output of the buffer 404 is inverted, the inverted output from the buffer 404 can be inverted by an inverter downstream from any buffer 404 (as shown in the example LL 310 and HL 312 of FIG. 4), thereby returning the inverted output from the buffer 404 to the original input value, which is propagated as an output of the latch.

Given the functions or operations of the buffers 404, the operation of the LL 310 and the HL 312 can be based on the DCLK signal. For example, when the DCLK signal is ‘0’, the CKT signal is ‘1’ and the CKB signal is ‘0’. In this case, the buffers 404B and 404C can be activated, thereby allowing the input signals to pass to the output, whereas the buffers 404A and 404D can be disconnected from the circuit. For the LL 310, because the buffer 404A is disconnected and the buffer 404B allows the input data to pass (forming a loop), the LL 310 can maintain the current value stored before the buffer 404A is disconnected. For the HL 312, because the buffer 404D is disconnected and the buffer 404C allows the input data to pass, the HL 312 can allow signal propagation from the input port of the HL 312 to the output. As such, the HL 312 can store or latch the input value carried by the input signal when the DCLK signal is ‘0’.

In further examples, when the DCLK signal is ‘1’, the CKT signal is ‘0’ and the CKB signal is ‘1’. In this case, the buffers 404A and 404D can be activated, thereby allowing the input signals to pass to the output, whereas the buffers 404B and 404C can be disconnected from the circuit. For the LL 310, because the buffer 404B is disconnected and the buffer 404A allows the input data to pass, the LL 310 can allow signal propagation from the input port of the LL 310 to the output. By allowing the signal propagation, the LL 310 can store or latch the input value carried by the input signal. For the HL 312, because the buffer 404C is disconnected and the buffer 404D allows its input data to pass, a loop can be formed, allowing the HL 312 to maintain the current value stored before the buffer 404C is disconnected, for example. It should be noted that other types of components (e.g., buffers, diodes, or transistors) may be utilized, formed, or implemented in the LL 310 or the HL 312 to perform similar features or functionalities discussed herein.

For purposes of providing examples herein, the operation of the LL 310 and the HL 312 may be described as allowing (signal) propagation or stopping (signal) propagation according to the DCLK signal. Allowing signal propagation can involve the latch transmitting the input signal to the output and storing the input data. Stopping signal propagation can involve the latch maintaining or holding the current data that is stored prior to stopping the propagation. In some cases, stopping the signal propagation can involve the latch preventing the input signal from being stored or disconnecting from the input port. For example, when DCLK is ‘0’, the LL 310 can allow signal propagation, and the HL 312 can stop signal propagation (or maintain the current value). When DCLK is ‘1’, the LL 310 can stop signal propagation, and the HL 312 can allow signal propagation.

Referring back to FIG. 3, in operation, when the DCLK is ‘0’, the LL 310 can allow propagation and storage of input data from the respective input pins 308A-D. For example, when the DCLK is ‘0’, the LL 310A can allow propagation (and storage) of the signal from the address pin 308A, the LL 310B can allow signal propagation from the address pin 308B, the LL 310C can allow signal propagation from the BWEB pin 308C, and the LL 310D can allow signal propagation from the data pin 308D. With the (inputs of) HLs 312A, 312C, 312D coupled to the outputs of LLs 310A, 310C, 310D, these HLs 312 can stop the signal propagation from the respective LLs 310 while the DCLK is ‘0’.

When the DCLK is set to ‘1’ (e.g., corresponding to the RCLK state), the LLs 310 can stop signal propagation and maintain the current value, e.g., the signals from the input pins do not affect the stored value of the LLs 310. The RCLK and DCLK can be set to ‘1’ in response to starting a clock cycle (e.g., receiving the CLK signal of ‘1’). In this case, the HLs 312A, 312C, 312D can allow signal propagation from the respective LLs 310A, 310C, 310D and store the value from the LLs 310A, 310C, 310D. Setting the DCLK to ‘1’ can be a part of a setup for the next or upcoming write operation. After the HLs 312A, 312C, 312D store the values from the respective LLs 310A, 310C, 310D, the write operation can be performed using values stored in the HLs 312A, 312C, 312D. For instance, the clock generator 314 can generate the WCLK signal to ‘1’ to initiate the write operation after a predefined timeframe or duration from generating the RCLK signal of ‘1’.

The RCLK, and thereby the DCLK, can be set to ‘0’ at any instance during the high state of the WCLK signal (or in some cases, after WCLK is set to ‘0’). By implementing the HLs 312A, 312C, 312D as shown in at least the schematic diagram 300, the corresponding address ABD and write data DT can be maintained in the HLs 312A, 312C, 312D to ensure a proper write operation by the memory device 100. Implementing the HLs 312 can avoid having hold racing, e.g., a time delay after the falling edge of the WCLK signal which ensures a proper write operation when an LL 310 is implemented without the HL 312.

Further, as shown in the schematic diagram 300, coupling the HL 312 to the LL 310 can reduce power consumption by the input pins 308. For example, without the HL 312, such as with LL 310B, the power consumption can be from the input pin 308B to the WL decoder 306, such as when the DCLK is set to ‘0’ to allow propagation via the LL 310B, among other components until a meeting point with a clock element (e.g., a component including the clock element). With the HL 312, such as HL 312A coupled to the LL 310A, the power consumption can be from the input pin 308A to the HL 312A during DCLK of ‘0’ or from the input pin 308A to the LL 310A during DCLK of ‘1’, thereby minimizing power consumption from the input pin 308 to other components of the memory device 100. The power consumption can be reduced with respective other input pins 308 coupled to the flip-flop interfaces (e.g., LLs 310 and HLs 312). The example timing of the read and write operation, and changes to the address ABD and the write data DT in a clock cycle can be described in conjunction with at least FIG. 5.

FIG. 5 illustrates an example timing diagram 500 for the operation of the memory device 100 using the flip-flop interfaces of FIG. 3, in accordance with various embodiments. The example operational timing of the timing diagram 500 can be performed by one or more components of the memory device 100, as described in conjunction with at least one of but not limited to FIGS. 3-4. At least one of the example timing discussed herein may be predefined, including at least one of the duration of the signal in the high state (e.g., ‘1’), the duration of the signal in the low state (e.g., ‘0’), the clock cycle time (e.g., the time duration for completing an operational cycle, including read and write operations), the time duration to generate the WCLK of ‘1’ after generating the RCLK of ‘1’ or vice versa, a setup racing time, etc. For purposes of providing examples, the operations discussed herein can be in relation to the flip-flops (e.g., LLs 310 and HLs 312) coupled to the address pin 308A, BWEB pin 308C, and data pin 308D for the write operation.

As an example, the clock signals (e.g., CLK, RCLK, WCLK, and DCLK) can be ‘0’ before the start of the clock cycle or prior to the clock generator 314 receiving CLK of ‘1’ from the clock pin 308E, for example. At this time, the DCLK signal which corresponds to the RCLK signal can be ‘0’, with the LLs 310 allowing signal propagation and the HLs 312 stopping signal propagation. As shown in the timing diagram 500, signals from the input pins 308C-D and the write data DT (e.g., stored in the HLs 312C-D) can be D1. Similarly, the signal from the input pin 308A and the address AAD can be A1.

Subsequently, different signals may be transmitted via the input pins 308A, 308C, 308D, including data D2 and address A2. Because the corresponding LLs 310A, 310C, 310D allow propagation, the LL 310A can store data A2 and the LLs 310C-D can store data D2. During DCLK of ‘0’, the corresponding HLs 312A, 312C, 312D can stop signal propagation, thereby preventing changes to the write data D1 (at 510) and the address A1. It should be noted that the HLs 312A, 312C, 312D can maintain other write data or addresses at this time, not limited to D1 or A1, for example.

At 502, the CLK signal can be generated (e.g., set to ‘1’) and received by the clock generator 314. At 504, in response to receiving the CLK ‘1’, the clock generator 314 can generate the RCLK signal of ‘1’ to initiate the read and write operation. Setting the RCLK signal to ‘1’ can also set the DCLK to ‘1’ (e.g., the latch clock signal is generated along with the read clock signal), at 508. It should be noted that there may be a delay between setting a clock signal as a response to another clock signal and/or performing an operation in response to a particular clock signal, for instance, in consideration of delays in signal transmission, signal processing time by one or more components of the memory device 100, etc.

Responsive to setting the DCLK to ‘1’, the LLs 310A, 310C, 310D can stop propagation (e.g., maintain current data A2 and D2) and the corresponding HLs 312A, 312C, 312D can allow propagation. As shown in the timing diagram 500, the HLs 312A, 312C, 312D can propagate the input signals and store the values (e.g., write data D2 and address A2) from the LLs 310A, 310C, 310D, at 512. The HLs 312A, 312C, 312D storing the write data D2 and address A2 can be a part of a setup for the next or upcoming write operation. Hence, the time duration from storing the write data D2 and the address A2 (e.g., address for the write operation) to the start of the WCLK (e.g., setting the WCLK to ‘1’) can be referred to as setup racing, e.g., at 514.

After the predefined duration from generating the high RCLK signal, the clock generator 314 can generate the WCLK signal of ‘1’, at 506. The memory device 100 (e.g., the write circuit 302 and the WL decoder 306) can use the stored values from the HLs 312A, 312C, 312D to perform the write operation. The RCLK signal can be reset to ‘0’ after a predefined duration, as well as the DCLK signal. With the DCLK set to ‘0’, the LLs 310A, 310C, 310D can allow propagation, and the HLs 312A, 312C, 312D can stop propagation. Because the HLs 312A, 312C, 312D maintain the current value, the memory device 100 can perform the write operation without extending the duration of the DCLK, e.g., the hold racing can be removed, thereby reducing the cycle time. For instance, as shown in the timing diagram 500, signals from the input pins 308A, 308C, 308D can change to write data D3 and address A3, but the respective HLs 312A, 312C, 312D can maintain the current value of write data D2 and address A2, such as until the next clock cycle.

FIG. 6 illustrates a schematic diagram 600 of scan flip-flop interfaces used for the memory device 100 of FIG. 1, in accordance with various embodiments. The schematic diagram 600 can include one or more components or circuits as described in conjunction with at least FIGS. 3-4. The one or more components shown in the schematic diagram 600 can perform features or functionalities similar to the one or more components as described in conjunction with at least FIGS. 3-4.

In various implementations, the area or size of the memory device 100 can be minimized for the implementation of the flip-flops (e.g., LLs 310 and HLs 312) by reusing certain components or circuits of the memory device 100. For example, the memory device 100 may include a plurality of shadow latches. The shadow latch may be a type of storage element in the memory device 100 for capturing and holding data. The one or more components of the shadow latches can be (re-)used as one or more scan flip-flops (e.g., existing scan flip-flops) including the LLs 310 and the HLs 312, as shown in portions 602A-B. In this case, the scan flip-flops can be coupled to and interposed between the respective input pins 308 and the one or more components.

For example, a first scan flip-flop can include the LL 310A and the HL 312A. A second scan flip-flop can include the LL 310B and the HL 312B. A third scan flip-flop can include the LL 310C and the HL 312C. A fourth scan flip-flop can include the LL 310D and the HL 312D. The inputs of the first to fourth scan flip-flops can be coupled to the input pins 308A-D, respectively. The outputs of the first and second scan flip-flops can be coupled to the WL decoder 306. The outputs of the first and second scan flip-flops can also be coupled to the write circuit 302 and the read circuit 304, respectively. The outputs of the third and fourth scan flip-flops can be coupled to the write circuit 302.

By reusing the shadow latches for the scan flip-flops, the area usage in the memory device 100 for implementing the LLs 310 and the HLs 312 can be minimized. Reusing the shadow latches can refer to utilizing existing shadow latches in the circuitry to function as the scan flip-flops, for example. It should be noted at least one HL 312 from the respective scan flip-flop (or shadow latch) may not be used for the read and write operation, such as the HL 312B. Other components or circuits may be included, not limited to those shown in the schematic diagram 300.

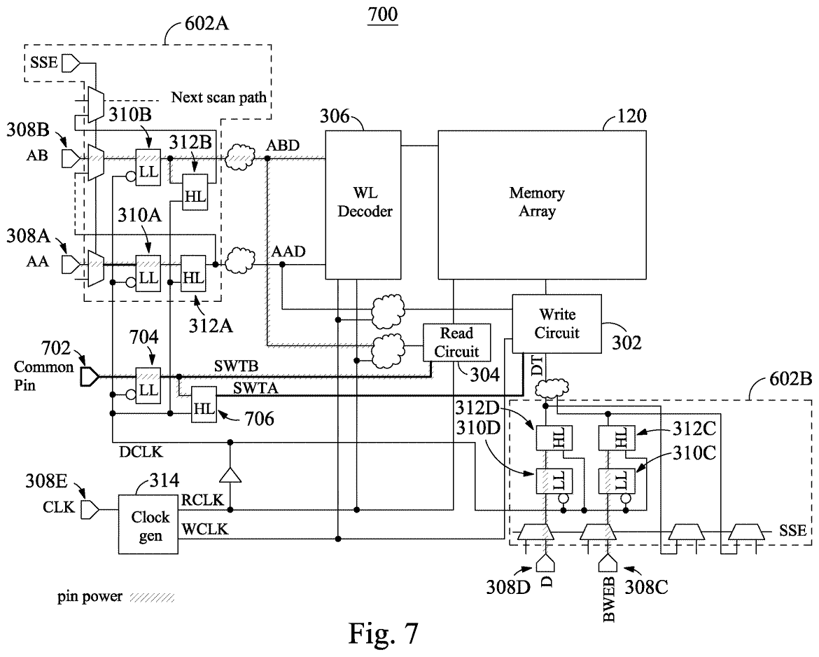

FIG. 7 illustrates a schematic diagram 700 of separating read signals and write signals from a common pin for the memory device 100 using the scan flip-flop interfaces of FIG. 6, in accordance with various embodiments. The schematic diagram 700 can include one or more components or circuits as described in conjunction with at least one of but not limited to FIGS. 3, 4, and 6. The one or more components shown in the schematic diagram 700 can perform features or functionalities similar to the one or more components as described in conjunction with at least FIGS. 3, 4, and 6.

As shown in the schematic diagram 700, the memory device 100 can include a common pin 702 coupled to the write circuit 302 and the read circuit 304. The common pin 702 can sometimes be referred to as a common line or common port, for example. The common pin 702 can be a shared control and data line used for the read operation and the write operation. Examples of the common pin 702 can include at least one of a switch (SWT), pipeline queue enable (PIPEQE), FAST, or SLOW, among others. The memory device 100 can include more than one common pin 702.

To use the common pin 702 for the read and write operations, the common pin 702 can be separated for the write circuit 302 and the read circuit 304. For example, the common pin 702 can be coupled to LL 704, e.g., carrying an input signal for the LL 704. The LL 704 can be coupled to the read circuit 304 and HL 706. The data from the LL 704 for the read circuit 304 and/or the HL 706 can be labeled as “SWTB”, e.g., sometimes referred to as SWTB data, signal, or value, carried via SWTB line for the read operation. The input of the HL 706 can be coupled to the LL 704 and the output of the HL 706 can be coupled to the write circuit 302. The data from the HL 706 for the write circuit 302 can be labeled as “SWTA”, e.g., sometimes referred to as SWTA data, signal, or value, carried via an SWTA line for the write operation. Therefore, the common pin 702 can be separated into a first line (e.g., SWTA line) and a second line (e.g., SWTB line). In some implementations, an output from the HL 706 can be referred to as an output of a flip-flop (e.g., a fourth flip-flop including the LL 704 and the HL 706).

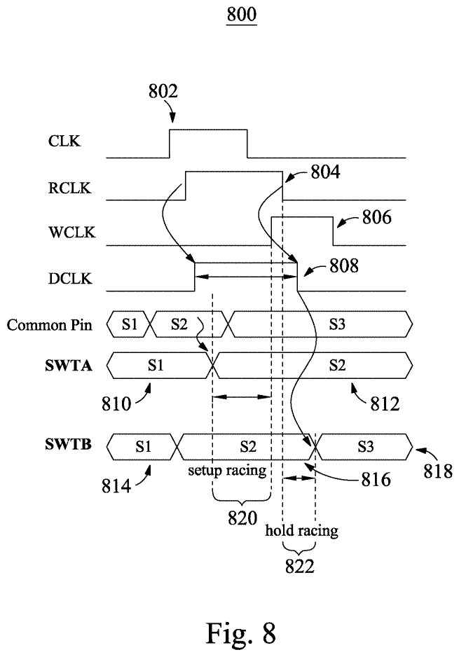

The LL 704 and the HL 706 can operate according to the DCLK signal (e.g., control signal carried by a control line) corresponding to the RCLK signal. The operations of the LL 704 and the HL 706 can be similar to other LLs 310 and HLs 312. For example, during DCLK set to ‘0’, the LL 704 can allow (signal) propagation from the common pin 702 to store the input data, and the HL 706 can stop propagation to maintain the current data. During DCLK set to ‘1’, the LL 704 can stop propagation, and the HL 706 can allow propagation. The operational timing of the LL 704 and the HL 706, and changes to the stored data according to the DCLK and the input data, can be described in conjunction with at least FIG. 8.

FIG. 8 illustrates an example timing diagram 800 for the operation of the memory device 100 using the scan flip-flop interfaces of FIG. 6 with the separated read and write signals of FIG. 7, in accordance with various embodiments. The example operational timing of the timing diagram 800 can be performed by one or more components of the memory device 100, as described in conjunction with at least one of but not limited to FIGS. 3, 4, 6, or 7. One or more examples operational timing of the timing diagram 800 can be similar to the example operational timing of the timing diagram 500. For example, the CLK signal at 802 can correspond to the CLK signal at 502. The RCLK signal at 804 can correspond to the RCLK signal at 504. The WCLK signal at 806 can correspond to the WCLK signal at 506. The DCLK signal at 808 can correspond to the DCLK signal at 508.

As shown, the timing diagram 800 can include changes to the SWTA data and SWTB data based on the DCLK signal and the input data from the common pin 702. One or more of the example operational timing discussed herein may be predefined, such as the duration, frequency, timing, etc. Prior to starting the clock cycle (or after a prior clock cycle), the RCLK, WCLK, and DCLK can be in a low state or set to ‘0’. During the low DCLK, the LL 704 can allow propagation, and the HL 706 can stop propagation. As shown in the timing diagram 800, the common pin 702 can carry data S1 as input to the LL 704. Because the LL 704 allows propagation, the LL 704 can store the input data S1 (e.g., at 814), while the HL 706 can maintain its currently stored data (e.g., at 810). For purposes of providing examples, the current data stored on the HL 706 can be data S1, although the HL 706 can maintain other data at this time, not limited to S1.

The data stored on the LL 704 can be the SWTB data used by the read circuit 304 for the read operation (e.g., during the high RCLK signal). The data stored on the HL 706 can be the SWTA data used by the write circuit 302 for the write operation (e.g., during the high WCLK signal). The data from the common pin 702 may change while the DCLK signal is in the low state. In this case, as shown in the timing diagram 800, input data from the common pin 702 can change from S1 to S2. The LL 704, which currently allows signal propagation according to a low DCLK signal, can store the input data S2, at 816. The HL 706 can maintain the current data S1.

Once the CLK signal is generated (e.g., set to ‘1’) at 802, the RCLK signal can be set to ‘1’ at 804 along with the DCLK signal set to ‘1’ in response to the RCLK signal, at 808. During DCLK of ‘1’, the LL 704 can stop propagation and the HL 706 can start propagation. As such, at 812, the HL 706 can propagate the signal and store the data S2 from the LL 704. The HL 706 can store the data S2 as a setup for the upcoming write operation. The duration from storing the data S2 and the rising edge of the WCLK signal can be referred to as setup racing, e.g., at 820. During the high RCLK signal, the read circuit 304 can perform the read operation using, at least in part, the SWTB data S2 from the LL 704. As shown at 822, hold racing may be applied for a predefined duration after the falling edge of the RCLK signal to ensure a proper read operation, e.g., prevent overriding the SWTB data during the read operation.

After a predefined time duration from generating the high RCLK signal, the WCLK signal can be generated (e.g., set to ‘1’), at 806. During the high WCLK signal, the write circuit 302 can perform the write operation, at least in part, using the SWTA data S2. The RCLK signal may be set to ‘0’ during the high state of the WCLK signal, thereby setting the DCLK signal to ‘0’. With the DCLK set to ‘0’, the HL 706 can stop propagation and maintain the current data S2. With the DCLK set to ‘0’, the LL 704 can allow propagation and store the input data. At 818, the LL 704 can store the input data S3 from the common pin 702. Therefore, the signal from the common pin 702 can be separated via a first output from the LL 704 (for the read operation) and a second output from the HL 706 (for the write operation).

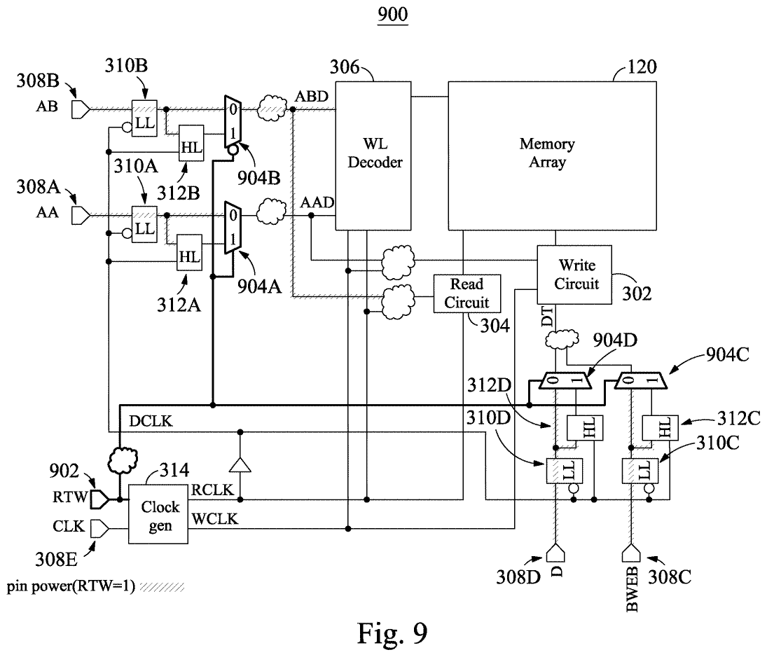

FIG. 9 illustrates a schematic diagram 900 of the memory device 100 using the flip-flop interfaces of FIG. 3 and including multiplexers (MUXs) 904A-D for selecting an operation mode, in accordance with various embodiments. The schematic diagram 900 can include one or more components or circuits as described in conjunction with at least one of but not limited to FIGS. 3, 4, 6, or 7. The one or more components shown in the schematic diagram 900 can perform features or functionalities similar to the one or more components as described in conjunction with at least one of but not limited to FIGS. 3, 4, 6, or 7. In various arrangements, the schematic diagram 900 can include additional components to those described in schematic diagram 300 of FIG. 3.

As shown, in addition to the components described in schematic diagram 300, the schematic diagram 900 can include an input pin 902 and a plurality of MUXs 904A-D. The input pin 902 can sometimes be referred to as a read-to-write (RTW) pin 902 or an operation selector pin, port, or line, for example. The MUXs 904A-D can sometimes be referred to as MUX(s) 904. Each MUX 904 can include a first input port, a second input port, a control port, and an output port. The input ports of each MUX 904 can be coupled to the output of the respective LL 310 and HL 312.

The control port of each MUX 904 can be coupled to the input pin 902, where signals from the input pin 902 can select one of the input ports to pass to the output, e.g., selecting one of the input signals as the output. The selection of one of the input ports can correspond to a selection of an operation mode for the memory device 100. The operation modes can include at least a write-then-read operation and a read-then-write operation. The output port of each MUX 904 can be coupled to the memory array 120 or intermediary components between the MUX 904 and the memory array 120, such as the WL decoder 306, the write circuit 302, or the read circuit 304.

For purposes of providing examples, a low signal (e.g., ‘0’) from the RTW pin 902 can represent the selection of the write-then-read operation, and a high signal (e.g., ‘1’) from the RTW pin 902 can represent the selection of the read-then-write operation. It should be noted that the control port of at least one MUX 904, e.g., MUX 904B, can be inverted to perform the desired read and write operation. In various implementations, the signals from the RTW pin 902 can be used for controlling the MUXs 904 and the generation of the RCLK signal or WCLK signal, such as whether the RCLK or the WCLK to be generated first or second in a clock cycle, based on the selected operation mode. For instance, if the signal via the RTW pin 902 is in a low state (e.g., ‘0’), representing a write-then-read operation, the WCLK signal can be generated (or set to ‘1’) before the RCLK signal. Otherwise, if the signal via the RTW pin 902 is in a high state (e.g., ‘1’), representing a read-then-write operation, the RCLK signal can be generated (or set to ‘1’) before the WCLK signal.

For example, when RTW pin 902 carries a low signal (e.g., ‘0’), the first input port (e.g., corresponding to the value of ‘0’) of MUXs 904A, 904C, 904D can be selected as the output. For MUX 904B, the second input port (e.g., corresponding to the value of ‘1’, inverted from the control signal of ‘0’) can be selected as the output. In this case, one or more features or operations as described in conjunction with at least one of but not limited to FIGS. 3-5 may be utilized to perform the write operation followed by the read operation. For instance, in this case, the input pin 308B can be coupled to a flip-flop, including LL 310B and HL 312B, while other input pins 308A, 308C, 308D can be coupled to the respective LLs 310A, 310C, 310D (e.g., outputs from the respective LLs 310A, 310C, 310D selected as the MUX output). Prior to the start of the clock cycle, the RCLK, WCLK, and DCLK can be set to ‘0’, thereby triggering the LLs 310 to allow propagation and the HLs 312 to stop propagation (e.g., during the low state of the DCLK signal). The LLs 310A, 310C, 310D can store the input data from the respective input pins 308A, 308C, 308D for the write circuit 302 to perform the write operation. The HLs 312B can maintain the current data for the read circuit 304 to perform the read operation.

At the start of the clock cycle, the WCLK signal can be generated or set to ‘1’. The DCLK can remain at ‘0’ corresponding to the state of the RCLK. During the high state of the WCLK signal, the write circuit 302 can execute the write operation using the write data DT from the LLs 310C-D and the address AAD from the LL 310A. After a predefined duration from generating the WCLK signal, the RCLK signal can be generated or set to ‘1’, leading to the DCLK set to ‘1’. By setting the DCLK to ‘1’, the HL 312B can allow propagation and storage of data from the LL 310B. The read circuit 304 can receive the address ABD stored in the HL 312B to perform the read operation. The address ABD can be maintained as the current data of the HL 312B after resetting the RCLK and the DCLK to ‘0’ until the next clock cycle, for example.

In another example, when RTW pin 902 carries a high signal (e.g., ‘1’), the second input port (e.g., corresponding to the value of ‘1’) of MUXs 904A, 904C, 904D can be selected as the output. For MUX 904B, the first input port (e.g., corresponding to the value of ‘0’, inverted from the control signal of ‘1’) can be selected as the output. In this case, the various components in the schematic diagram 900 may perform or execute features or operations similar to those described in conjunction with at least one of but not limited to FIGS. 3-5. The memory device 100 discussed herein may include additional or alternative features, operations, or functionalities not limited to those discussed herein.

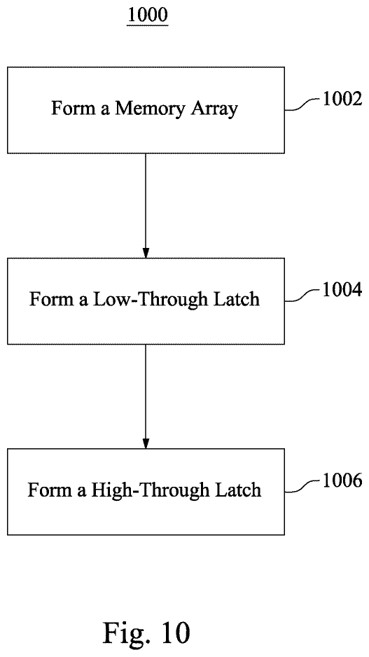

FIG. 10 illustrates a flow of an example method 1000 for forming the memory device (e.g., 100) of at least one of FIGS. 1-9, in accordance with some embodiments. The method 1000 can be performed to form any of memory devices herein or a portion thereof. For example, the method 1000 can be performed to form any of the memory devices or a component thereof discussed with respect to at least one of FIGS. 1-9. For example, at least one of operations of the method 1000 may be performed to form a memory device (e.g., 100). Accordingly, the following discussion of the method 1000 may refer to some of the reference numerals used in at least one of FIGS. 1-9 as a non-limiting example. Further, the method 1000 is merely an example, and is not intended to limit the present disclosure. It should thus be understood that additional operations may be provided before, during, and after the method 1000 of FIG. 10, and that some other operations may only be briefly described herein. The method 1000 can be performed simultaneously and/or in any order other than the order depicted in FIG. 10.

The method 1000 can start with operation 1002 of forming a memory array (e.g., 120). The formed memory array can include a plurality of memory cells (e.g., 125). Each of the plurality of memory cells can be a static random access memory (SRAM) cell configured to perform a read-and-write operation in one clock cycle. For instance, in each clock cycle, the memory device or circuit can perform read and write operations.

The method 1000 can continue to operation 1004 of forming a low-through latch (LL) (e.g., 310) coupled to a pin (e.g., 308) and a control line (e.g., DCLK line). The control line can carry a clock signal (e.g., DCLK signal). The formed LL can be referred to as a first LL. The method 1000 can continue to operation 1006 of forming a high-through latch (HL) (e.g., 312) coupled to the LL, the control line, and the memory array. The HL can be referred to as a first HL.

In various implementations, the input of the HL can be coupled to the output of the LL. The output of the HL can be coupled to the memory array. The control line can be coupled to the control port of the LL and the HL to control the operations of the LL and the HL. For example, the HL can be configured to propagate signals when the clock signal (received via the control port) is high (e.g., ‘1’) and stop (signal) propagation of the signals when the clock signal is low (e.g., ‘0’). Allowing the propagation can include passing the input signal to the output and storing the data or value of the input signal. Stopping the propagation can include maintaining the current value or data stored in the latch. In further examples, the LL can be configured to propagate signals when the clock signal is low and stop propagation of the signals when the clock signal is high. The operation of the LL (to allow or stop propagation) can be opposite to the HL with the same clock signal.

Each pair of LL and HL can form a flip-flop (e.g., a flip-flop interface). For instance, the first LL and the first HL can form a first flip-flop interposed between a first address pin (e.g., 308A) and the memory array. The first address pin may be configured for a write operation, e.g., used by a write circuit (e.g., 302) to perform the write operation to one or more memory cells corresponding to the data of the first address pin.

For operating the LL and/or the HL, the method 1000 can include forming a clock generator (e.g., 314) coupled to a clock pin and configured to generate a first clock signal and a second clock signal. The clock signal of the control line can correspond to one of the first clock signal or the second clock signal. For example, the first clock signal can be a read clock signal and the second clock signal can be a write clock signal. The clock generator can generate the clock signal (e.g., set the state of the clock cycle) for the LL and HL based on the state of the read clock signal (e.g., RCLK signal).

In some implementations, the first clock signal can refer to a low clock signal and the second clock signal can refer to a high clock signal, or vice versa. The clock generator can set the clock signal as the first clock signal (e.g., for low state) or the second clock signal (e.g., for high state) according to the state of the read clock signal.

In various implementations, the method 1000 can include forming other flip-flops, such as a second flip-flop and a third flip-flop. The second flip-flop can include a second LL (e.g., 310D) electrically connected to a second HL (e.g., 312D). The second flip-flop can be coupled to a data pin (e.g., 308D). The third flip-flop can include a third LL (e.g., 310C) electrically connected to a third HL (e.g., 312C). The third flip-flop can be coupled to a BWEB pin (e.g., 308C).

In some implementations, the method 1000 can include forming a WL decoder (e.g., 306) interposed between and coupled to at least the HL (e.g., the first HL) and the memory array. The method 1000 can include forming a write circuit (e.g., 302) coupled to the first, second, and third HLs, and configured to output a signal to the memory array. In some cases, the method 1000 can include forming a fourth LL (e.g., 310B) electrically coupled to a second address pin (e.g., 308B). In some implementations, the method 1000 can include forming a read circuit (e.g., 304) coupled to the fourth LL and the memory array. The second address pin can be configured to provide signals (e.g., address value) for a read operation performed by the read circuit. In the read operation, the read circuit can be configured to receive a signal from the memory array.

Each of the LL and the HL can include two tri-state buffers and an inverter, e.g., to allow signal propagation or stop signal propagation. In some implementations, the memory device or circuit can include at least one shadow latch including (or re-use for) at least one scan flip-flop. The LL and the HL can be a part of the scan flip-flop. The shadow latch and/or the scan flip-flop (e.g., 602A-B) may be (e.g., existing) components or circuits from other parts of the memory device.

In some implementations, the method 1000 can include forming another LL (e.g., 704) and another HL (e.g., 706), sometimes referred to as a second LL and a second HL, for example. The second LL can be coupled to a common pin (e.g., 702), the control line carrying the clock signal, and the read circuit. The second HL can be coupled to the second LL, the control line, and the write circuit. For instance, the output of the second LL can be coupled to the input of the second HL and the read circuit. The output of the second HL (e.g., sometimes referred to as an output from the flip-flop comprising the second LL and the second HL) can be coupled to the write circuit. A signal from the common pin can be separated via a first output (e.g., SWTB) from the second LL and a second output (e.g., SWTA) from the second HL, for example.

In some configurations, the method 1000 can include forming a multiplexer (e.g., 904). The multiplexer can include a first input port coupled to the LL. The multiplexer can include a second input port coupled to the HL. The multiplexer can include a control port coupled to a selector pin (e.g., 902) configured to select an operation mode of the memory circuit. The multiplexer can include an output port coupled to the memory array. The multiplexer can be configured to output signals from one of the LL or the HL according to a signal from the selector pin. For example, the first input port may correspond to signal ‘0’ from the selector pin and the second input port may correspond to signal ‘1’ from the selector pin, or vice versa. Hence, the output from the multiplexer can be a value one of the first input port or the second input port according to the signal (e.g., state or value) from the selector pin. The operation mode can include a write-then-read operation and a read-then-write operation. For instance, the signal ‘0’ from the selector pin can be used for the write-then-read operation and the signal ‘1’ can be used for the read-then-write operation, or vice versa.

In some implementations, the plurality of LLs and HLs can be referred to as a first, second, third, fourth latches, etc. For example, the first LL can be referred to as a first latch. The first HL can be referred to as a second latch. The second LL can be referred to as a third latch. The second HL can be referred to as a fourth latch. The third LL can be referred to as a fifth latch. The third HL can be referred to as a sixth latch. The fourth LL can be referred to as a seventh latch, etc.

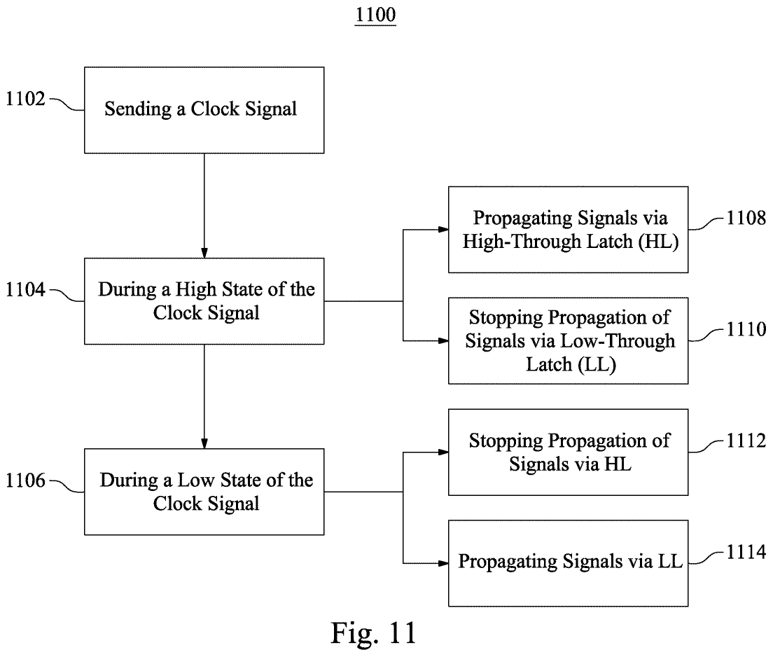

FIG. 11 illustrates a flow of an example method 1100 for operating the memory device (e.g., 100) of at least one of FIGS. 1-9, in accordance with some embodiments. The method 1100 can be performed to operate any memory devices herein or a portion thereof. For example, the method 1100 can be performed to operate any memory devices or components thereof discussed with respect to at least one of FIGS. 1-9. For example, at least one of operations of the method 1100 may be performed to operate or perform features or functionalities of (one or more components of) a memory device (e.g., 100). Accordingly, the following discussion of the method 1100 may refer to some of the reference numerals used in at least one of FIGS. 1-9 as a non-limiting example. Further, the method 1100 is merely an example, and is not intended to limit the present disclosure. It should thus be understood that additional operations may be provided before, during, and after the method 1100 of FIG. 11, and that some other operations may only be briefly described herein. The method 1100 can be performed simultaneously and/or in any order other than the order depicted in FIG. 11.

The method 1100 can start with operation 1102 of sending a clock signal (e.g., DCLK). The clock signal can be generated by a clock generator (e.g., 314) according to signals from the clock pin 308E. For example, in response to receiving a high signal (e.g., ‘1’) at the clock pin, the clock generator can generate a read clock signal (e.g., RCLK) followed by a write clock signal (e.g., WCLK), such as described in conjunction with at least FIG. 5. Generating the RCLK and/or WCLK can refer to outputting or setting a high signal (e.g., ‘1’) for sending or transmission via the respective signal lines, e.g., RCLK line or WCLK line. For purposes of providing examples, the clock signal (e.g., DCLK) can correspond to the RCLK, where the operations of the latches, such as LL (e.g., 310) and HL (e.g., 312), are controlled by the DCLK, for example.

In various configurations, the memory device can include a memory array (e.g., 120), including a plurality of memory cells (e.g., 125). Each of the plurality of memory cells can be a static random access memory (SRAM) cell configured to perform a read-and-write operation in one clock cycle. For instance, in each clock cycle, the memory device or circuit can perform read and write operations. The memory device can include one or more LLs and one or more HLs. At least one LL can be coupled to an HL and a corresponding pin, such as an address pin (e.g., 308A), data pin (e.g., 308D), BWEB pin (e.g., 308C), etc. Each pair of LL and HL can form a flip-flop, for example. In various implementations, the operation of each pair of LL and HL may be similar to one or more other pairs of LL and HL. For purposes of providing examples herein, the operations described herein can be for one of the LL and HL pairs, although similar operations or functionalities can be described for other pairs of LLs and HLs.

The method 1100 can continue to operation 1104 for the functions of the LL and HL during a high state of the clock signal (e.g., DCLK). The high state of the clock signal can refer to when the clock signal is ‘1’, and a low state of the clock signal can refer to when the clock signal is ‘0’. During the high clock signal, signals can propagate via the HL (at operation 1108), e.g., the HL can allow signal propagation. On the other hand, during the high clock signal, signals may stop propagating via the LL (at operation 1110), e.g., the LL can prevent signal propagation.

The method 1100 can continue to operation 1106 for the functions of the LL and HL during the low state of the clock signal. During the low clock signal, signals can stop propagating via the HL (at operation 1112). Further, during the low clock signal, signals can propagate via the LL (at operation 1114). Propagating the signals via the latch or allowing propagation of the signal can involve allowing the input data to pass the latch, thereby changing the value stored in the respective latch. For example, by allowing signal propagation via the LL, the LL can store or latch the input value carried by the input signal, e.g., from the pin. In this example, the value (e.g., bit value) stored at the LL can change during the signal propagation (e.g., during low clock signal). Similarly, by allowing signal propagation via the HL, the HL can store or latch the input value from the LL (e.g., the value stored or latched by the LL). In such cases, the stored value at the HL can correspond to the value stored at the HL during signal propagation (e.g., during the high clock signal).

Stopping signal propagation can involve the latch maintaining or holding the current data or value that is stored prior to stopping the propagation, e.g., the latest value propagated. For example, by preventing or stopping signal propagation via the LL, the LL can maintain or store the latest value from the pin prior to stopping the signal propagation. In another example, by stopping signal propagation via the HL, the HL can maintain or store the latest value from the LL prior to stopping the signal propagation. The values from the HL can be used for an access operation, such as a write operation performed using the value stored in the HL, e.g., address and data, for writing to the memory cell, for example.

By implementing the HL and LL (e.g., the flip-flop), power consumption by the pin can be minimized because the power consumption can be reduced to, for instance, between the pin and one of the respective LL or HL, corresponding to the meeting point with the clock signal, e.g., instead of the between the input pin and the various other components downstream from the input pin of the memory device. Further, because the one or more HLs can maintain the current value, the memory device can perform the write operation without extending the duration of the DCLK, e.g., the hold racing can be removed, thereby reducing the cycle time.

In one aspect of the present disclosure, a memory circuit is disclosed. The memory circuit includes a memory array comprising a plurality of memory cells. The memory circuit includes a low-through latch (LL) coupled to a pin and a control line, wherein the control line carries a clock signal. The memory circuit includes a high-through latch (HL) coupled to the LL, the control line, and the memory array. The HL is configured to propagate signals when the clock signal is high and stop propagation of the signals when the clock signal is low. The LL is configured to propagate signals when the clock signal is low and stop propagation of the signals when the clock signal is high.

In another aspect of the present disclosure, a memory circuit is disclosed. The memory circuit includes a memory array comprising a plurality of memory cells. The memory circuit includes a first latch coupled to a pin and a control line carrying a clock signal. The memory circuit includes a second latch coupled to the first latch, the control line, and the memory array. The first latch is configured to propagate signals when the clock signal is low and stop propagation of the signals when the clock signal is high. The second latch is configured to propagate signals when the clock signal is high and stop propagation of the signals when the clock signal is low.

In yet another aspect of the present disclosure, a method for operating a memory device having a memory array comprising a plurality of memory cells is disclosed. The method includes sending a clock signal in a low state or a high state to a low-through latch (LL) and a high-through latch (HL) via a control line, wherein the LL is coupled to a pin and the control line, and the HL is coupled to the LL, the control line, and the memory array. During the high state of the clock signal, the method includes propagating signals via the HL and stopping propagation of signals via the LL. During the low state of the clock signal, the method includes propagating signals via the LL and stopping propagation of signals via the HL.

As used herein, the terms “about” and “approximately” generally indicate the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

As used herein, the terms “about” and “approximately” generally indicate the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

I foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is

1. A memory circuit, comprising:
a memory array comprising a plurality of memory cells configured to perform a first operation and a second operation within one clock cycle;
a clock generator configured to generate a first clock signal and a second clock signal within the one clock cycle, wherein the second clock signal is generated subsequent to the first clock signal;
a low-through latch (LL) coupled to a pin and a control line carrying a third clock signal, the third clock signal corresponding to the first clock signal; and
a high-through latch (HL) coupled to the LL, the control line, and the memory array,
wherein the HL is configured to (i) store a value from the LL responsive to the third clock signal transitioning to a high state, and (ii) maintain the stored value during the second operation, and
wherein a setup racing is defined from the HL storing the value from the LL to a rising edge of the second clock signal.

2. The memory circuit of claim 1, wherein the first operation is a read operation and the second operation is a write operation, and wherein the first clock signal is a read clock signal associated with the read operation, the second clock signal is a write clock signal associated with the write operation, and the third clock signal is a latch clock signal corresponding to the read clock signal.

3. The memory circuit of claim 1, wherein to the second clock signal subsequent to the first clock signal, the clock generator is configured to generate the second clock signal after a predefined duration from the first clock signal.

4. The memory circuit of claim 1, wherein the setup racing corresponds to a duration from a first time at which the HL stores the value from the LL to a second time associated with the rising edge of the second clock signal, such that the stored value in the HL is stable for the second operation prior to the second clock signal transitioning to the high state.

5. The memory circuit of claim 1, wherein the third clock signal is configured to transition to a low state independent of a falling edge of the second clock signal, and wherein the HL maintains the stored value after the third clock signal transitions to the low state.

6. The memory circuit of claim 1, wherein the LL is configured to propagate signals from the pin when the third clock signal is in a low state and to stop propagation of signals from the pin when the third clock signal is in the high state.

7. The memory circuit of claim 1, wherein the LL is configured to store input data from the pin prior to the third clock signal transitioning to the high state, and wherein the stored input data in the LL is provided as input to the HL responsive to the third clock signal transitioning to the high state.

8. The memory circuit of claim 1, wherein the LL and the HL form a first flip-flop coupled to a first address pin configured for the second operation, and wherein the memory circuit further comprises:
a second flip-flop comprising a second LL electrically connected to a second HL, the second flip-flop coupled to a data pin; and
a third flip-flop comprising a third LL electrically connected to a third HL, the third flip-flop coupled to a bit write enable bit (BWEB) pin, wherein the second flip-flop and the third flip-flop are coupled to the control line carrying the third clock signal.

9. The memory circuit of claim 8, further comprising:
a fourth LL electrically coupled to a second address pin and the control line, the second address pin configured for the first operation; and
a read circuit coupled to the fourth LL and the memory array, the read circuit configured to receive a signal from the memory array during the first operation.

10. The memory circuit of claim 1, further comprising:
a write circuit coupled to the HL and the memory array, the write circuit configured to perform the second operation using the stored value in the HL during a high state of the second clock signal; and
a word line decoder interposed between the HL and the memory array, the word line decoder configured to decode an address stored in the HL to select a memory cell within the memory array.

11. The memory circuit of claim 1, wherein the HL maintaining the stored value during the second operation allows the third clock signal to transition to a low state prior to or during the second operation without affecting the stored value used for the second operation, which reduces a cycle time for performing the first operation and the second operation within the one clock cycle.

12. The memory circuit of claim 1, wherein each of the LL and the HL comprises two buffers and an inverter, and wherein each of the plurality of memory cells is a static random access memory (SRAM) cell configured to perform the first operation and the second operation in the one clock cycle.

13. A memory circuit, comprising:
a memory array comprising a plurality of memory cells;
an input pin;
a low-through latch (LL) having (i) an input coupled to the input pin and (ii) an output, the LL coupled to a control line carrying a clock signal; and
a high-through latch (HL) having (i) an input coupled to the output of the LL and (ii) an output coupled to a circuit associated with the memory array for performing a memory operation, the HL coupled to the control line,
wherein the HL is configured to propagate signals when the clock signal is high and stop propagation of the signals when the clock signal is low,
wherein the LL is configured to propagate signals when the clock signal is low and stop propagation of the signals when the clock signal is high, and
wherein a signal propagation path from the input pin is bounded by one of the LL or the HL based on a state of the clock signal.

14. The memory circuit of claim 13, wherein the circuit associated with the memory array comprises at least one of a word line decoder, a write circuit, or a read circuit, and wherein the output of the HL is coupled to at least one of the word line decoder, the write circuit, or the read circuit.

15. The memory circuit of claim 13, wherein the LL and the HL form a first flip-flop coupled to the input pin, and wherein the memory circuit further comprises:
a plurality of flip-flops, each of the plurality of flip-flops comprising a respective LL and a respective HL coupled to a respective input pin and the control line,
wherein for each of the plurality of flip-flops, a signal propagation path from the respective input pin is bounded by one of the respective LL or the respective HL based on the state of the clock signal.

16. The memory circuit of claim 15, wherein the input pin is an address pin configured for a write operation, and wherein the plurality of flip-flops are coupled to at least a data pin and a bit write enable bit (BWEB) pin.

17. The memory circuit of claim 13, further comprising:
a clock generator configured to generate a first clock signal and a second clock signal, the clock signal of the control line corresponding to the first clock signal,
wherein the HL is configured to (i) store a value from the LL responsive to the clock signal transitioning to a high state, and (ii) maintain the stored value during a high state of the second clock signal, and
wherein the LL is configured to store an input value from the input pin for a subsequent clock cycle during the high state of the second clock signal.

18. The memory circuit of claim 13, wherein the signal propagation path extends from the input pin to the LL when the clock signal is low and from the input pin to the HL when the clock signal is high, such that the signal propagation path is confined between the input pin and one of the LL or the HL.

19. A method for operating a memory device having a memory array comprising a plurality of memory cells configured to perform a read operation and a write operation within one clock cycle, the method comprising:
generating, by a clock generator, a first clock signal and a second clock signal within the one clock cycle, wherein the second clock signal is generated subsequent to the first clock signal;
sending a third clock signal in a low state or a high state to a low-through latch (LL) and a high-through latch (HL) via a control line, wherein the LL is coupled to a pin and the control line, and the HL is coupled to the LL, the control line, and the memory array, and wherein the third clock signal corresponds to the first clock signal;
during the low state of the third clock signal, propagating signals via the LL to store a value from the pin and stopping propagation of the signals via the HL;
transitioning the third clock signal to the high state, wherein responsive to transitioning the third clock signal to the high state, the HL stores the value from the LL and the LL stops propagation of signals from the pin; and
performing the write operation using the value stored in the HL during a high state of the second clock signal, wherein the HL maintains the stored value during the write operation, and wherein a setup racing is defined from the HL storing the value from the LL to a rising edge of the second clock signal.

20. The method of claim 19, comprising:
performing the read operation during a high state of the first clock signal,
wherein a signal propagation path from the pin is bounded by one of the LL or the HL based on the state of the third clock signal, the signal propagation path extending from the pin to the HL when the third clock signal is in the low state and from the pin to the LL when the third clock signal is in the high state, such that the signal propagation path is confined between the pin and one of the LL or the HL.
